(19) United States
(12) Patent Application Publication
(10) Pub. No.: US 2011/0102292 A1
(43) Pub. Date: May 5, 2011

(54) DEVICE HOUSING AND METHOD FOR MAKING THE SAME

(75) Inventors: YE XIONG, Shenzhen (CN); WEI-DONG HAO, Shenzhen (CN)

(73) Assignees: SHENZHEN FUTAIHONG PRECISION INDUSTRY CO., LTD., ShenZhen City (CN); FIH (HONG KONG) LIMITED, Kowloon (HK)

(21) Appl. No.: 12/850,719

(22) Filed: Aug. 5, 2010

(30) Foreign Application Priority Data
Oct. 29, 2009 (CN) 200910309050.7

(51) Int. Cl. H01Q 1/40; C23C 14/28; B05D 5/12

(52) U.S. Cl. 343/873; 427/595; 427/58

(57) ABSTRACT

A device housing has a transparent or translucent film, an antenna, and a substrate. The antenna is a conductive coating designed and configured in a pattern and is formed on portions of one surface of the film. The substrate is molded on the antenna and on the area of the film not covered by the antenna. A method for making the device housing is also described.

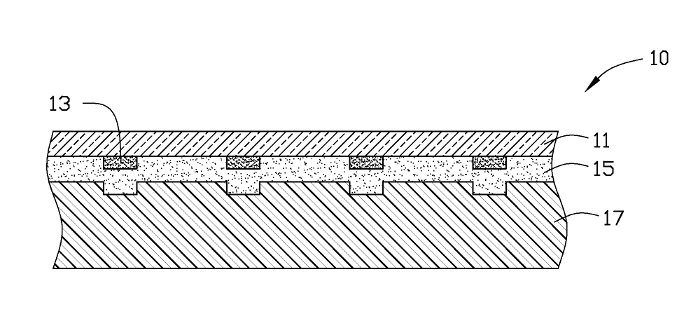

### BACKGROUND

1. Technical Field

The present disclosure relates to device housings, especially to a device housing having an antenna formed thereon and a method for making the device housing.

2. Description of Related Art

Antennas are critical for wireless communication with electronic devices (such as mobile phones, computers, PDAs, and so on). The antenna is usually smaller and thinner to save space and decrease weight of the electronic device, and is further shaped in an aesthetic pattern to make the electronic device more attractive to customers. This kind of antenna, for example, a thin piece of metal film, is typically directly attached to the surface of the electronic device; however, it is at risk of abrasion and may even fall off after a period of usage time.

Therefore, there is room for improvement within the art.

### BRIEF DESCRIPTION OF THE FIGURE

Many aspects of the device housing can be better understood with reference to the following figure. The components in the figure are not necessarily drawn to scale, the emphasis instead being placed upon clearly illustrating the principles of the device housing.

The figure is a schematic view of an exemplary embodiment of a device housing.

### DETAILED DESCRIPTION

Referring to the figure, in this exemplary embodiment, a device housing 10 includes a film 11, an antenna 13 formed on the film 11, a protective coating 15 formed on the antenna 13 and the film 11, and a substrate 17 combined with the protective coating 15.

The film 11 may be made of transparent or translucent plastic. The plastic material of the film 11 may be selected from a group consisting of polypropylene (PP), polyamide (PA), polycarbonate (PC), polyethylene terephthalate (PET), and polymethyl methacrylate (PMMA).

The antenna 13 may be, for example, a conductive ink coating formed by silk-screen printing. The conductive paint used for the antenna 13 may contain a plurality of conductive agents, for example, silver powder or copper powder. The conductive paint further contains a plurality of resins, hardening agents, and additives. The additives may be pigments, surface treating agents, flowable agents, and extenders. The antenna 13 is formed on a plurality of portions of one surface of the film 11 in a desired pattern according to a predefined design and configuration for the antenna 13. Alternatively, the antenna 13 can also be a vapor deposited metal coating or a thin piece of metal film.

The protective coating 15 may be, for example, an ink coating formed on the antenna 13 and on a plurality of areas of the film 11 not covered by the antenna 13. The ink used for the protective coating 15 may be ultraviolet (UV) curable ink. The protective coating 15 can be transparent or opaque. The protective coating 15 may be in different colors so as to appear more aesthetically attractive.

The substrate 17 may be, for example, a plastic coating made of a thermoplastic material, and is molded on the protective coating 15. The thermoplastic material may be selected from a group consisting of polypropylene (PP), polyamide (PA), polycarbonate (PC), polyethylene terephthalate (PET), and polymethyl methacrylate (PMMA).

It is to be understood that, the protective coating 15 is not necessary, and the substrate 17 can be directly molded on the antenna 13 and the film 11.

The device housing 10 has a plurality of advantages such as the following: The antenna 13 may be attractively designed and configured in a particular pattern and in a plurality of colors viewable through the transparent or translucent film 11. The antenna 13 is defined between the film 11 and the protective coating 15, and accordingly, the antenna 13 cannot be easily abraded. Additionally, the antenna 13 can be securely attached in the device housing 10.

A method for manufacturing the device housing 10 may include of the following: a transparent or translucent film is provided; a conductive coating on various portions of one surface of the film in a desired pattern is formed to obtain an antenna; and a substrate is molded on the antenna and the film.

Specifically, the transparent or translucent film 11 is provided.

The conductive coating is formed on several portions of the film 11 in one or more desired patterns and colors to obtain the antenna 13. The antenna 13 may be, for example, a conductive ink coating, a vapor deposited metal coating, or a thin piece of metal film.

The protective coating 15 is applied on the antenna 13 and the film 11. The protective coating 15 can protect the antenna 13 from abrasion when molding with the substrate 17. The protective coating 15 can be an UV curable ink coating possessing excellent high temperature resistance.

The film 11 combined with the protective coating 15 is then disposed in a mold (not shown), and a substrate 17 is molded on the protective coating 15.

It is to be understood that, the protective coating 15 is not necessary, and the substrate 17 can be directly molded on the antenna 13 and the film 11.

It should be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A device housing, comprising:
a transparent or translucent film;
an antenna formed on a plurality of portions of one surface of the film; and
a substrate combined with the antenna and the film;
wherein the antenna is a conductive coating and is configured in a pattern; and the substrate is molded on the antenna and the film.

2. The device housing as claimed in claim 1, wherein the antenna is a conductive ink coating formed by silk-screen printing.

3. The device housing as claimed in claim 1, wherein the antenna is a vapor deposited metal coating.

4. The device housing as claimed in claim 1, wherein the antenna is a piece of metal film.

5. The device housing as claimed in claim 1, wherein the substrate is made of thermoplastic.

6. The device housing as claimed in claim 5, wherein the thermoplastic is selected from a group consisting of polypropylene, polyamide, polycarbonate, polyethylene terephthalate, and polymethyl methacrylate.

7. The device housing as claimed in claim 1, further comprising a protective coating formed between the antenna and the substrate, and the substrate combined with the protective coating.

8. The device housing as claimed in claim 7, wherein the protective coating is an UV curable ink coating.

9. The device housing as claimed in claim 1, wherein the film is made of plastic selected from a group consisting of polypropylene, polyamide, polycarbonate, polyethylene terephthalate, and polymethyl methacrylate.

10. A method for making a device housing, comprising:
providing a transparent or translucent film;
forming a conductive coating on a plurality of portions of one surface of the film in a pattern to obtain an antenna; and
molding a substrate on the antenna and the film.

11. The method as claimed in claim 10, wherein forming the conductive coating is carried out by printing a conductive ink on the portions of one surface of the film.

12. The method as claimed in claim 10, wherein forming the conductive coating is carried out by vapor depositing a metal coating on the portions of one surface of the film.

13. The method as claimed in claim 10, wherein forming the conductive coating is carried out by defining a piece of metal film on the portions of one surface of the film.

14. The method as claimed in claim 10, further comprising a step of printing a protective coating on the antenna before molding the substrate.

15. The method as claimed in claim 14, wherein the protective coating is an UV curable ink coating.

16. The method as claimed in claim 10, wherein the film is made of plastic selected from a group consisting of polypropylene, polyamide, polycarbonate, polyethylene terephthalate, and polymethyl methacrylate.
